(19) United States
(12) Patent Application Publication
(10) Pub. No.: US 2025/0105168 A1
(43) Pub. Date: Mar. 27, 2025

(54) ELECTROMAGNETIC SHIELDING STRUCTURE AND PACKAGING METHOD

(71) Applicant: FOREHOPE ELECTRONIC (NINGBO) CO., LTD., Ningbo City (CN)

(72) Inventors: Zhenghong HE, Ningbo City (CN); Yupeng XU, Ningbo City (CN); Lei ZHONG, Ningbo City (CN); Li LI, Ningbo City (CN)

(21) Appl. No.: 18/891,987

(22) Filed: Sep. 20, 2024

(30) Foreign Application Priority Data
Sep. 22, 2023 (CN) 2023112272487

(51) Int. Cl. H01L 23/552; H01L 21/48; H01L 23/06; H01L 23/31; H01L 23/498; H01L 23/538; H01L 25/00; H01L 25/065

(52) U.S. Cl. CPC H01L 23/552; H01L 21/4853; H01L 23/06; H01L 23/49816; H01L 25/0655; H01L 25/50; H01L 23/3107; H01L 23/5383

(57) ABSTRACT

Electromagnetic shielding structure and packaging method are provided. Electromagnetic shielding structure includes substrate, first device, second device, shielding wire, edge wire, encapsulation, and shielding metal layer. Substrate is provided with shielding and non-shielding regions; and wire-bonding pad and grounding pad, with grounding pad positioned farther from shielding region compared to wire-bonding pad. First device is located in shielding region, and second device is located in non-shielding region. Shielding wire is electrically connected to wire-bonding pad, and edge wire is electrically connected to grounding pad. Edge wire is located on side of shielding wire farther from shielding region. Grounding pad and wire-bonding pad are electrically connected. Encapsulation encapsulates first device, second device, shielding wire, and edge wire, with shielding wire exposed from encapsulation. Shielding metal layer covers encapsulation, and is electrically connected to shielding wire.

### CROSS-REFERENCE TO RELATED APPLICATIONS

The present disclosure claims priority to the Chinese patent application with the filing No. 2023112272487 filed with the Chinese Patent Office on Sep. 22, 2023, and entitled “ELECTROMAGNETIC SHIELDING STRUCTURE AND PACKAGING METHOD”, the contents of which are incorporated herein by reference in their entirety.

### TECHNICAL FIELD

The present disclosure relates to the technical field of semiconductor packaging, and particularly to an electromagnetic shielding structure and packaging method.

### BACKGROUND ART

Through research conducted by the inventors, it has been found that the existing partitioned EMI (Electro-magnetic Interference) shielding technology mainly includes using the wire bonding to produce a cage-like shielding region structure. The bonding pad of the grounding wiring layer of the conventional substrate is arranged around the chip, serving as the grounding point for the shielding region to achieve the shielding function. Since the high-frequency signal transmission between the chip and the substrate needs to be conducted through the wiring layers within the substrate, multiple wiring layers need to be designed for routing, such as high-frequency signal lines, power lines, and grounding wiring layers. Among them, the upper end of the grounding wiring layer is led out through the grounding pad to achieve the grounding shielding function. If a large number of grounding pads are designed, the number of wiring layers and the length of the grounding wiring layer will inevitably increase, which can easily cause parasitic effects and capacitive effects between multiple wiring layers, thereby affecting the electromagnetic shielding effect.

### SUMMARY

An electromagnetic shielding structure is provided, including a substrate, wherein the substrate is provided with a shielding region and a non-shielding region, the substrate is provided with a wire-bonding pad and a grounding pad, and the grounding pad is located farther from the shielding region relative to the wire-bonding pad; a first device, arranged in the shielding region; a second device, arranged in the non-shielding region; a shielding wire, wherein the shielding wire is electrically connected to the wire-bonding pad; an edge wire, wherein the edge wire is electrically connected to the grounding pad, the edge wire is located on a side of the shielding wire that is farther from the shielding region, and the grounding pad and the wire-bonding pad are electrically connected; an encapsulation, wherein the encapsulation encapsulates the first device, the second device, the shielding wire, and the edge wire, and the shielding wire is exposed from the encapsulation; and a shielding metal layer, wherein the shielding metal layer is arranged on a side of the encapsulation that is farther from the substrate, and the shielding metal layer is electrically connected to the shielding wire.

An electromagnetic shielding structure is provided, including a substrate, wherein the substrate is provided with a shielding region and a non-shielding region, the substrate is provided with wire-bonding pads, the wire-bonding pads form the shielding region, and a grounding wiring layer is provided within the substrate; a first device, arranged in the shielding region; a second device, arranged in the non-shielding region; a shielding wire, wherein the shielding wire is electrically connected to the wire-bonding pad; an encapsulation, wherein the encapsulation encapsulates the first device, the second device, and the shielding wire, and the shielding wire is exposed from the encapsulation; and a shielding metal layer, wherein the shielding metal layer covers the encapsulation, the shielding metal layer is electrically connected to the shielding wire, and the grounding wiring layer extends to a sidewall of the substrate and is electrically connected to the shielding metal layer.

An electromagnetic shielding packaging method is provided, including: providing a substrate, wherein the substrate is provided with a shielding region and a non-shielding region, the substrate is provided with wire-bonding pads, the wire-bonding pads form the shielding region, and a grounding wiring layer extending to the sidewall of the substrate is provided within the substrate; mounting a first device in the shielding region; bonding a shielding wire on the wire-bonding pad; forming an encapsulation on the substrate that covers the first device and the shielding wire, wherein the shielding wire is exposed from the encapsulation; and forming a shielding metal layer that is electrically connected to both the shielding wire and the grounding wiring layer on the surface of the encapsulation.

### BRIEF DESCRIPTION OF DRAWINGS

In order to more clearly illustrate the technical solutions of the embodiments of the present disclosure, the following will briefly introduce the drawings used in the embodiments. It should be understood that the following drawings only show some embodiments of the present disclosure, and therefore it should not be regarded as a limitation on the scope. Those ordinary skilled in the art can also obtain other related drawings based on these drawings without inventive effort.

FIG. 1 is a schematic diagram of a first structure of an electromagnetic shielding structure provided in the embodiment of the present disclosure;

FIG. 2 is a schematic diagram of a first layout structure of a grounding pad and a wire-bonding pad on a substrate of an electromagnetic shielding structure provided in the embodiment of the present disclosure;

FIG. 3 is a schematic diagram of a second structure of an electromagnetic shielding structure provided in the embodiment of the present disclosure;

FIG. 4 is a schematic diagram of a third structure of an electromagnetic shielding structure provided in the embodiment of the present disclosure;

FIG. 5 is a schematic diagram of a second layout structure of a grounding pad and a wire-bonding pad on a substrate of an electromagnetic shielding structure provided in the embodiment of the present disclosure;

FIG. 6 is a schematic diagram of a third layout structure of a grounding pad and a wire-bonding pad on a substrate of an electromagnetic shielding structure provided in the embodiment of the present disclosure;

FIG. 7 is a schematic diagram of a fourth layout structure of a grounding pad and a wire-bonding pad on a substrate of an electromagnetic shielding structure provided in the embodiment of the present disclosure;

FIG. 8 is a schematic diagram of a fourth structure of an electromagnetic shielding structure provided in the embodiment of the present disclosure;

FIG. 9 is a schematic diagram of a fifth structure of an electromagnetic shielding structure provided in the embodiment of the present disclosure;

FIG. 10 is a schematic diagram of a sixth structure of an electromagnetic shielding structure provided in the embodiment of the present disclosure;

FIG. 11 is a schematic diagram of a seventh structure of an electromagnetic shielding structure provided in the embodiment of the present disclosure;

FIG. 12 is a schematic diagram of an eighth structure of an electromagnetic shielding structure provided in the embodiment of the present disclosure; and

FIGS. 13 and 14 are process flow diagrams of an electromagnetic shielding structure provided in the embodiment of the present disclosure.

### REFERENCE NUMERALS

100-electromagnetic shielding structure;

110-substrate;

111-wire-bonding pad;

112-second pad;

113-grounding pad;

115-grounding wiring layer;

116-wiring layer;

117-groove;

118-solder mask;

120-first device;

130-second device;

140-shielding wire;

150-edge wire;

160-encapsulation;

170-shielding metal layer;

171-top metal layer;

173-sidewall metal layer;

180-underfill;

190-solder ball.

### DETAILED DESCRIPTION OF EMBODIMENTS

In order to make the objectives, technical solutions, and advantages of the embodiments of the present disclosure clearer, the technical solutions in the embodiments of the present disclosure will be clearly and completely described below in conjunction with the drawings in the embodiments of the present disclosure. It is evident that the described embodiments are part of the embodiments of the present disclosure, but not all of the embodiments. The components of the embodiments of the present disclosure described and illustrated in the drawings can typically be arranged and designed in various configurations.

Therefore, the following detailed description of the embodiments of the present disclosure provided in the drawings is not intended to limit the scope of the present disclosure for which protection is claimed, but merely represents selected embodiments of the present disclosure. Based on the embodiments of the present disclosure, all other embodiments obtained by those skilled in the art without inventive effort shall fall within the scope of protection of the present disclosure.

It should be noted that similar numerals and letters denote similar terms in the following drawings so that once an item is defined in one drawing, it does not need to be further discussed in subsequent drawings.

In the description of the present disclosure, it should be noted that the terms “center”, “top”, “bottom”, “left”, “right”, “vertical”, “horizontal”, “inside”, “outside”, and other directional or positional relationships indicated are based on the directional or positional relationships shown in the drawings, or the customary orientation or positional relationships when the product of the present disclosure is used. These terms are merely for the convenience of describing the present disclosure and simplifying the description, and are not intended to indicate or imply that the referenced devices or elements must have a specific orientation, be constructed, or operate in a specific orientation. Therefore, they should not be understood as limitations on the present disclosure. In addition, the terms “first”, “second”, and “third” are only used to distinguish the descriptive and are not to be construed as indicating or implying relative importance.

In addition, terms such as “horizontal” and “vertical” do not mean that elements are required to be absolutely horizontal or overhanging, but can be slightly inclined. For example, “horizontal” only means that its direction is more horizontal than “vertical”, and it does not mean that the structure must be completely horizontal, but can be slightly inclined.

In the description of the present disclosure, it should also be noted that unless otherwise clearly stipulated and limited, the terms “provide”, “mount”, “interconnect”, and “connect” should be understood in a broad sense, for example, it can be a fixed connection, a detachable connection, or an integral connection; it can be a mechanical connection or an electrical connection; and it can be a direct connection, an indirect connection through an intermediary, or an internal communication between two components. Those of ordinary skill in the art can understand the meanings of the above terms in the present disclosure according to specific situations.

The present disclosure provides an electromagnetic shielding structure and packaging method, which can reduce the parasitic effects and capacitive effects generated between multiple wiring layers in the substrate, thereby enhancing the electromagnetic shielding effect.

The embodiments of the present disclosure are implemented as follows.

In a first aspect, the present disclosure provides an electromagnetic shielding structure, including a substrate, wherein the substrate is provided with a shielding region and a non-shielding region, the substrate is provided with a wire-bonding pad and a grounding pad, and the grounding pad is located farther from the shielding region relative to the wire-bonding pad; a first device, arranged in the shielding region; a second device, arranged in the non-shielding region; a shielding wire, wherein the shielding wire is electrically connected to the wire-bonding pad; an edge wire, wherein the edge wire is electrically connected to the grounding pad, the edge wire is located on a side of the shielding wire that is farther from the shielding region, and the grounding pad and the wire-bonding pad are electrically connected; an encapsulation, wherein the encapsulation encapsulates the first device, the second device, the shielding wire, and the edge wire, and the shielding wire is exposed from the encapsulation; and a shielding metal layer, wherein the shielding metal layer is arranged on a side of the encapsulation that is farther from the substrate, and the shielding metal layer is electrically connected to the shielding wire.

In one or more embodiments, a grounding wiring layer is provided within the substrate, and a projection of the grounding wiring layer on the surface of the substrate is located in the non-shielding region. The grounding pad is electrically connected to the grounding wiring layer.

In one or more embodiments, the grounding pad and the wire-bonding pad are connected using metal wires and/or conductive adhesive.

In one or more embodiments, the shielding metal layer includes a top metal layer and a sidewall metal layer that are connected, wherein a shielding barrier is formed around the first device, and the shielding barrier is jointly formed by the sidewall metal layer and multiple shielding wires.

In one or more embodiments, the shielding metal layer includes a top metal layer and a sidewall metal layer that are connected, with at least partial wire-bonding pads exposed from a sidewall of the encapsulation to electrically connect with the sidewall metal layer.

In one or more embodiments, the substrate is provided with multiple grounding pads, and the grounding pads are electrically connected to any of the wire-bonding pads.

In one or more embodiments, the wire-bonding pad is arranged in the shielding region, and multiple grounding pads are arranged in the non-shielding region;

and at least two of the grounding pads are electrically connected by the edge wire, with one of the grounding pads and the wire-bonding pad connected through a wiring layer.

In one or more embodiments, the shielding metal layer covers the encapsulation and the sidewall of the substrate.

In one or more embodiments, a solder mask is provided on the substrate, with the grounding pad and the wire-bonding pad exposed from the solder mask.

In one or more embodiments, a groove is provided on the substrate, with partial grounding wiring layer exposed from the groove. A conductive adhesive is provided within the groove, and the conductive adhesive is configured to connect the wire-bonding pad and the grounding pad.

In one or more embodiments, a solder mask is provided on the substrate, and the groove is provided on the solder mask.

In one or more embodiments, an underfill is further included, wherein the underfill covers the edge wire and partially covers the shielding wire.

In one or more embodiments, the grounding pad is designed as an equipotential grounding signal layer.

In a second aspect, the present disclosure provides an electromagnetic shielding structure, including a substrate, wherein the substrate is provided with a shielding region and a non-shielding region, the substrate is provided with wire-bonding pads, the wire-bonding pads form the shielding region, and a grounding wiring layer is provided within the substrate; a first device, arranged in the shielding region; a second device, arranged in the non-shielding region; a shielding wire, wherein the shielding wire is electrically connected to the wire-bonding pad; an encapsulation, wherein the encapsulation encapsulates the first device, the second device, and the shielding wire, and the shielding wire is exposed from the encapsulation; and a shielding metal layer, wherein the shielding metal layer covers the encapsulation, the shielding metal layer is electrically connected to the shielding wire, and the grounding wiring layer extends to a sidewall of the substrate and is electrically connected to the shielding metal layer.

In a third aspect, the present disclosure provides an electromagnetic shielding packaging method, including providing a substrate, wherein the substrate is provided with a shielding region and a non-shielding region, the substrate is provided with wire-bonding pads, the wire-bonding pads form the shielding region, and a grounding wiring layer extending to the sidewall of the substrate is provided within the substrate; mounting a first device in the shielding region; bonding a shielding wire on the wire-bonding pad; forming an encapsulation on the substrate that covers the first device and the shielding wire, wherein the shielding wire is exposed from the encapsulation; and forming a shielding metal layer that is electrically connected to both the shielding wire and the grounding wiring layer on the surface of the encapsulation.

In a fourth aspect, the present disclosure provides an electromagnetic shielding packaging method, including providing a substrate, wherein the substrate is provided with a shielding region and a non-shielding region, the substrate is provided with wire-bonding pads and grounding pads, the wire-bonding pads form the shielding region, and the grounding pad is located farther from the shielding region relative to the wire-bonding pad; mounting a first device in the shielding region; bonding a shielding wire on the wire-bonding pad; bonding an edge wire on the grounding pad;

forming an encapsulation on the substrate that covers the first device, the shielding wire, and the edge wire, wherein the shielding wire is exposed from the encapsulation; and forming a shielding metal layer on the surface of the encapsulation that is electrically connected to the shielding wires, respectively.

The embodiments of the present disclosure include the following beneficial effects.

The embodiment of the present disclosure provides an electromagnetic shielding structure and a packaging method. By separately designing the wire-bonding pad and the grounding pad, and designing the grounding pad farther from the shielding region relative to the wire-bonding pad, this helps to reduce the number and length of grounding wiring layers in the substrate. As a result, the parasitic effects and the capacitive effects generated between multiple wiring layers in the substrate are reduced, thereby enhancing the electromagnetic shielding effect. In addition, the embodiment also includes a shielding metal layer, with the shielding metal layer and the shielding wire each providing electromagnetic shielding functions, thereby enhancing the electromagnetic shielding effect.

The technical solution of the present disclosure is described in further detail below by means of specific embodiments.

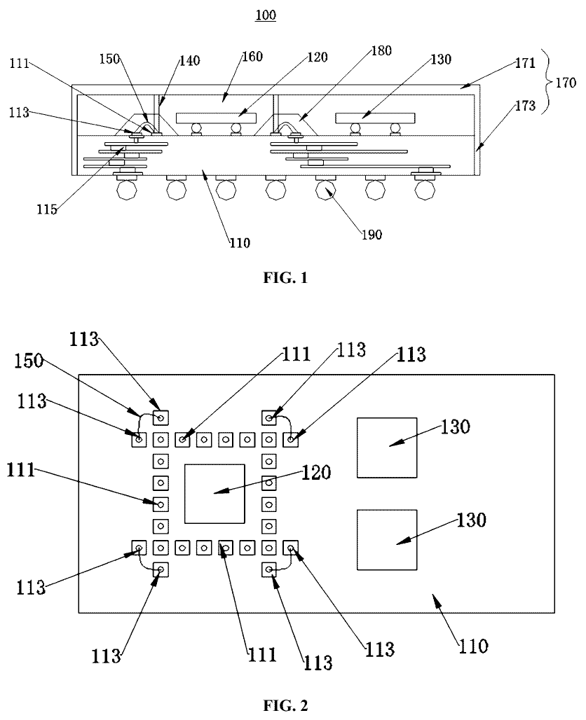

Referring to FIG. 1 and FIG. 2, the embodiment provides an electromagnetic shielding structure 100, which includes a substrate 110, a first device 120, a second device 130, a shielding wire 140, an edge wire 150, an encapsulation 160, and a shielding metal layer 170. The substrate 110 is provided with a shielding region and a non-shielding region. The substrate 110 is provided with a wire-bonding pad 111 and a grounding pad 113, wherein the wire-bonding pads 111 enclose to form the shielding region. The grounding pad 113 is located farther from the shielding region relative to the wire-bonding pad 111. The first device 120 is located in the shielding region, and the second device 130 is located in the non-shielding region. The shielding wire 140 is electrically connected to the wire-bonding pad 111, and the edge wire 150 is electrically connected to the grounding pad 113. The edge wire 150 is located on the side of the shielding wire 140 which is farther from the shielding region. The grounding pad 113 and the wire-bonding pad 111 are electrically connected. The encapsulation 160 encapsulates the first device 120, the second device 130, the shielding wire 140, and the edge wire 150, with the shielding wire 140 exposed from the encapsulation 160. The shielding metal layer 170 is provided on the side of the encapsulation 160 that is farther from the substrate 110, and the shielding metal layer 170 is electrically connected to the shielding wire 140. By separately designing the wire-bonding pad 111 and the grounding pad 113, and designing the grounding pad 113 farther from the shielding region relative to the wire-bonding pad 111, this helps to reduce the number and length of grounding wiring layers 115 in the substrate 110. As a result, parasitic effects and capacitive effects between multiple wiring layers 116 in the substrate 110 are reduced, thereby enhancing the electromagnetic shielding effect. In addition, the embodiment also includes a shielding metal layer 170, with the shielding metal layer 170 and the shielding wire 140 each providing electromagnetic shielding functions, thereby enhancing the electromagnetic shielding effect.

It should be noted that electro-magnetic compatibility (EMC) interference can easily occur between wiring layers in the substrate 110. For signal lines and circuits in the wiring layers, differential mode interference current flowing through the wiring layer loop can cause differential mode interference radiation, and such a loop essentially forms a ring-shaped antenna structure, thereby resulting in radiated magnetic fields that produce interference signals and interference electromagnetic waves. If the chip generates a common mode interference current on the wiring layers, strong electromagnetic radiation is generated from the circuit wiring layers, which can cause electromagnetic interference to the chip. Furthermore, when the circuit is unbalanced, common mode interference current can convert to differential mode interference current, and the differential mode interference current directly interferes with and affects the circuit. When differential mode interference current flows through the wiring layer loop, it can cause differential mode interference radiation, and such a loop essentially forms a ring-shaped antenna structure, thereby resulting in radiated magnetic fields that produce interference signals and interference electromagnetic waves, affecting the chip performance.

The embodiment reduces the number of grounding wiring layers 115 in the substrate 110, thereby reducing the impact of differential mode interference or common mode interference on chip performance.

Optionally, the shielding metal layer 170 covers the encapsulation 160 and the sidewall of the substrate 110, i.e., covering the upper surface and the side surface of the encapsulation 160, and the sidewall of the substrate 110.

The substrate 110 is provided with a grounding wiring layer 115, and an area of the grounding wiring layer 115 projected on the surface of the substrate 110 is located in the non-shielding region. The grounding pad 113 is electrically connected to the grounding wiring layer 115. It can be understood that the upper end of the grounding wiring layer 115 is extended through the grounding pad 113. Since the grounding wiring layer 115 is located beneath the non-shielding region of the substrate 110, this reduces the number of wiring layers beneath the shielding region of the substrate 110, thereby reducing parasitic effects and capacitive effects between multiple wiring layers 116 in the substrate 110, and improving the electromagnetic shielding effect. Additionally, with this arrangement, the grounding pad 113 has more design options and design flexibility.

In one or more embodiments, the shielding metal layer 170 includes a top metal layer 171 and sidewall metal layer 173 that are connected, with the top metal layer 171 located on the upper surface of the encapsulation 160 and the sidewall metal layer 173 located on the side surface of the encapsulation 160. A shielding barrier is formed around the first device 120, wherein the shielding barrier is jointly formed by the sidewall metal layer 173 and multiple shielding wires 140. It can be understood that if the shielding wires 140 form a cage-like structure, i.e., if the shielding wires 140 are provided surrounding the first device 120, this provides shielding for the first device 120. At the same time, the top metal layer 171 and the sidewall metal layer 173 covering the surface of the encapsulation 160 also provide shielding for the first device 120, thus achieving a dual-layer shielding effect and enhancing shielding performance.

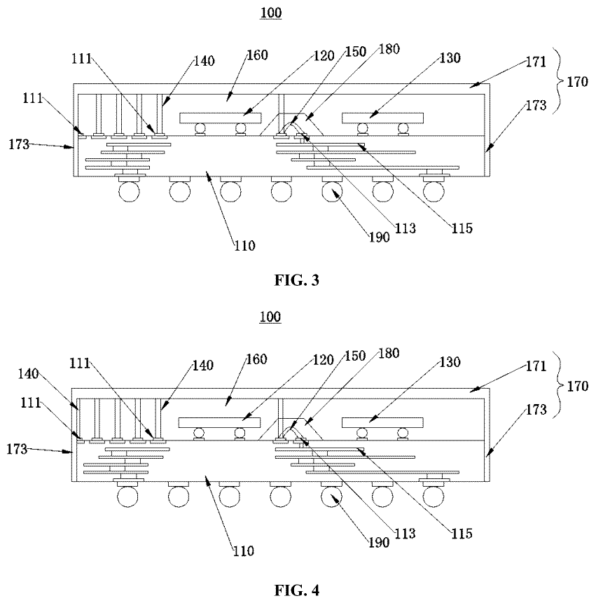

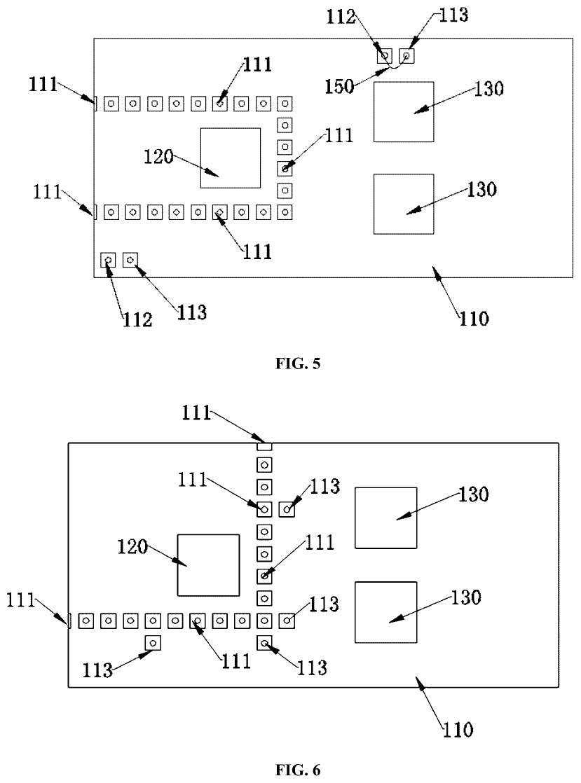

It can be understood that the sidewall metal layer 173 and the multiple shielding wires 140 are located on the same side of the first device 120. The region of the sidewall metal layer 173 projected on the side surface of the encapsulation 160 and the regions of the multiple shielding wires 140 projected on the side surface of the encapsulation 160 overlap at least partially, thus enabling dual-layer shielding. In conjunction with FIG. 3 and FIG. 5, alternatively, the sidewall metal layer 173 and the multiple shielding wires 140 are located on different sides of the first device 120 to achieve single-layer shielding. For example, if the first device 120 is of a rectangular prism with four side surfaces, and if the shielding wires 140 are provided on three of the side surfaces, shielding is achieved on the three side surfaces and the remaining side surface can use the sidewall metal layer 173 to achieve shielding function. This also achieves full shielding and reduces the design of the shielding wires 140, the design of the wire-bonding pads 111, and the wire-bonding edge of the cage-like structure, thus improving the area utilization ratio of the substrate 110. Alternatively, two side surfaces of the first device 120 use the shielding wires 140 for shielding, and the other two side surfaces use the sidewall metal layer 173 for shielding, as shown in FIG. 6. Alternatively, one side surface of the first device 120 uses the shielding wires 140 for shielding, and the other three side surfaces use the sidewall metal layer 173 for shielding. Thus, the first device 120 achieves shielding functionality through the combined use of the shielding metal layer 170 and the shielding wires 140.

It should be noted that the sidewall metal layer 173 can be arranged on the side with the shielding wires 140 to achieve dual-layer shielding, or it can be arranged on the side without the shielding wires 140 for single-layer shielding. Depending on the type of the first device 120 and the actual application scenario, the shielding barrier surrounding the first device 120 can be a fully enclosed ring structure; or, it can be a semi-enclosed structure, i.e., an open structure, such as shielding only one, two, or three side surfaces. This is not specifically limited.

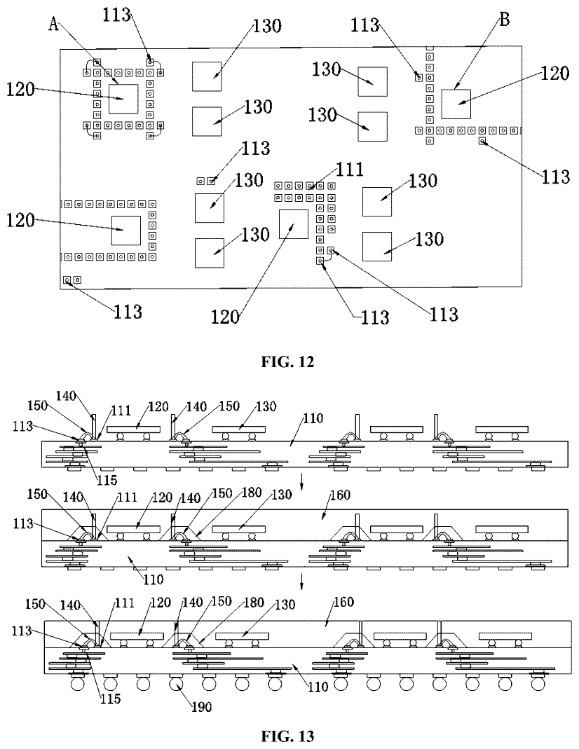

It should be understood that to enhance electromagnetic shielding performance, regardless of whether the shielding wires 140 are arranged in an open or closed structure, the shielding wires 140 around the first device 120 can be designed in a single row, double rows, or multiple rows, as illustrated in FIG. 12. Additionally, the shielding wires 140 can be designed in multiple rows in localized regions, such as two or three rows of shielding wires 140 arranged side-by-side or in a staggered manner, or the whole shielding wires 140 can be designed in multiple rows. This is not specifically limited.

In one or more embodiments, the grounding pad 113 can be designed in various ways. The grounding pad 113 and the wire-bonding pad 111 can be connected by metal wires and/or conductive adhesive. For instance, the grounding pad 113 can be arranged close to the wire-bonding pad 111, with the grounding pad 113 located on the side of the wire-bonding pad 111 that is away from the first device 120. In this case, one end of the edge wire 150 is connected to the grounding pad 113, and the other end is connected to the wire-bonding pad 111, achieving grounding of the shielding wire 140 and thus enabling the shielding function. In other words, the grounding pad 113 and the wire-bonding pad 111 are electrically connected by metal wires (e.g., the edge wire 150).

Alternatively, it is also possible that the edge wire 150 is connected to the grounding pads 113 at two different locations. By arranging the underfill 180 between the edge wire 150 and the shielding wire 140, the edge wire 150 and the shielding wire 140 are electrically connected through the underfill 180. It is easy to understand that the underfill 180 is conductive, such as conductive adhesive. Of course, it could also be a solder paste or a polymer epoxy, etc. Optionally, the underfill 180 can cover the edge wire 150 and partially cover the shielding wire 140. This arrangement of the edge wire 150 can help mitigate the impact of the molding flow on the arc of the shielding wire 140 and improve the capillary action of the underfill 180. Certainly, in some embodiments, metal wires can be applied between the grounding pad 113 and the wire-bonding pad 111 before filling with conductive adhesive, which is not specifically limited here.

If the shielding wire 140 is arranged in a cage-like structure, the wire-bonding pad 111 is arranged in a rectangular pattern around the first device 120. The grounding pad 113 can be arranged at the four corners of the rectangle, as shown in FIG. 2, with two grounding pads 113 arranged at each corner and two grounding pads 113 respectively located on the extended lines of two edges. Of course, the grounding pad 113 can also be arranged outside the middle of each edge, or in other locations. The number of grounding pads 113 can be adjusted based on actual conditions, with more grounding pads 113 to be arranged to improve the reliability of grounding electrical connections.

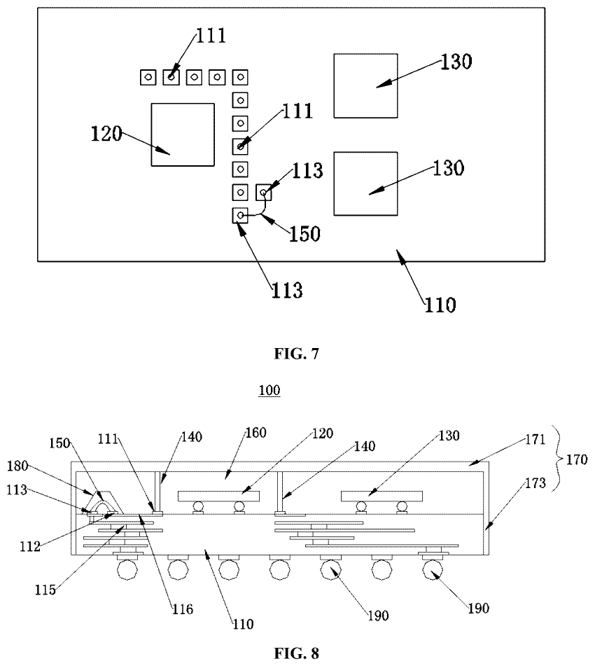

Alternatively, in conjunction with FIGS. 5 to 7, if the shielding wire 140 is not arranged in a cage-like structure but in an open structure such as L-shaped, U-shaped, T-shaped, or other shapes to achieve zoned shielding, the grounding pad 113 can be arranged at the middle of each edge, at the junction of two edges, at the end of each edge, or other positions for flexible arrangement. In one or more embodiments, the substrate 110 is provided with multiple grounding pads 113, wherein each grounding pad 113 can be electrically connected to one or more wire-bonding pads 111. This includes, but is not limited to, using at least one of conductive adhesive, metal wires, or internal wiring layers 116 to achieve the electrical connection, as shown in FIG. 6. Alternatively, the edge wire 150 can be electrically connected to any shielding wire 140. The edge wire 150 can be connected to any wire-bonding pad 111 by bonding, and designing multiple grounding pads 113 can enhance electrical conductivity, thereby improving the electromagnetic shielding effect.

In conjunction with FIGS. 5 and 8, in one or more embodiments, the grounding pads 113 and some of the wire-bonding pads 111 can also be arranged further from the shielding region. For example, if the wire-bonding pad 111 includes first pads and second pads 112, the first pads form the shielding region. The second pad 112 and the grounding pad 113 are arranged further from the shielding region. The first pad and the second pad 112 can be connected through the wiring layers 116 within the substrate 110. This allows for more design options and flexible design location for the grounding pad 113.

In some embodiments, certainly, multiple grounding pads 113 can be arranged in the non-shielding region, and the grounding pads 113 can be designed in pairs. For instance, two grounding pads 113 can be connected by the edge wire 150. One of the grounding pads 113 can be electrically connected to the wire-bonding pad 111 through the wiring layers 116 within the substrate 110. This allows for more design options and flexible design location for the grounding pad 113. The position and quantity of the grounding pads 113 can be flexibly adjusted, and no specific limitations are imposed herein. It is understood that, since one of the grounding pads 113 is electrically connected to the wire-bonding pad 111 through the wiring layers 116 within the substrate 110, the conductive adhesive can be used to cover only the edge wire 150. Of course, the edge wire 150 and the shielding wire 140 can also be electrically connected through the conductive adhesive to achieve electromagnetic shielding effects.

Arranging the grounding pads 113 farther from the wire-bonding pads 111 can help prevent the current effects and capacitive effects produced by the wiring layers 116 from impacting the shielding performance. This also shortens the routing length of the grounding wiring layer 115, allowing the grounding wiring layer 115 to be arranged farther from the shielding region, thus preventing signal interference between the wiring layers in the substrate 110, such as high-frequency signal lines and power lines, beneath the shielding region.

In one or more embodiments, at least some of the wire-bonding pads 111 extend from the sidewall of the encapsulating body 160 to electrically connect with the sidewall metal layer 173. For example, as shown in FIGS. 3 to 5, some of the wire-bonding pads 111 are arranged on the sawing path of the substrate 110. After encapsulating the first device 120, the second device 130, the shielding wire 140, and the edge wire 150, the encapsulating body 160 and the substrate 110 are sawed. At this point, the wire-bonding pads 111 located on the sawing path is exposed from the sidewall of the substrate 110. Subsequently, a shielding metal layer 170 is sputtered, and the sidewall metal layer 173 in the shielding metal layer 170 is electrically connected to the exposed wire-bonding pads 111 to achieve electromagnetic shielding. It can be understood that the wire-bonding pads 111 reserved on the sawing path can be left unbonded when bonding the shielding wire 140, thus facilitating their exposure after sawing and simplifying the process. This arrangement allows part of the heat from the shielding wire 140 to be conducted through the wire-bonding pads 111 to the sidewall of the substrate 110, and another part of the heat is dissipated through the top metal layer 171 so as to improve heat dissipation performance. One, two, three, or more of the wire-bonding pads 111 can be reserved on the sawing path.

In conjunction with FIG. 4, in some embodiments, a shielding wire 140 is provided on at least partial wire-bonding pads 111 that are exposed from the sidewall of the encapsulating body 160 and is electrically connected to the wire-bonding pads 111. In other words, the wire-bonding pads 111 reserved on the sawing path will also be bonded when the shielding wires 140 are bonded. During the subsequent sawing and separation process, the shielding wire 140 on the sawing path is partially sawed causing the shielding wire 140 to be exposed from the sidewall of a single encapsulating body 160. Optionally, the remaining thickness of the shielding wire 140 after sawing on the sawing path is about 1 μm to 25 μm, preferably 1 μm to 3 μm. In this way, the exposed shielding wire 140 serves as a seed layer for subsequent sputtering or electroplating of the shielding metal layer 170, which helps improve the bonding strength between the shielding metal layer 170 and the sidewall of the encapsulating body 160, thereby avoiding the issue of poor bondability between traditional EMI metal layers and the encapsulating body. Moreover, the shielding wire 140, acting as a bonding layer, increases the conductive area for grounding, effectively reduces the impedance of the grounding return path, and enhances the electromagnetic shielding effect. Additionally, this also contributes to improved thermal performance.

It is understood that after forming the encapsulating body 160 on the substrate 110, which encapsulates the first device 120 and the second device 130, the encapsulating body 160 needs to be ground so that the shielding wire 140 is exposed on the upper surface of the encapsulating body 160. Afterward, the sawing is performed. Since the shielding wire 140 is exposed during the sawing process, the shielding wire 140 on the sawing path can serve as a position reference for sawing, thereby improving sawing accuracy. This also facilitates the control of the sawing thickness of the shielding wire 140.

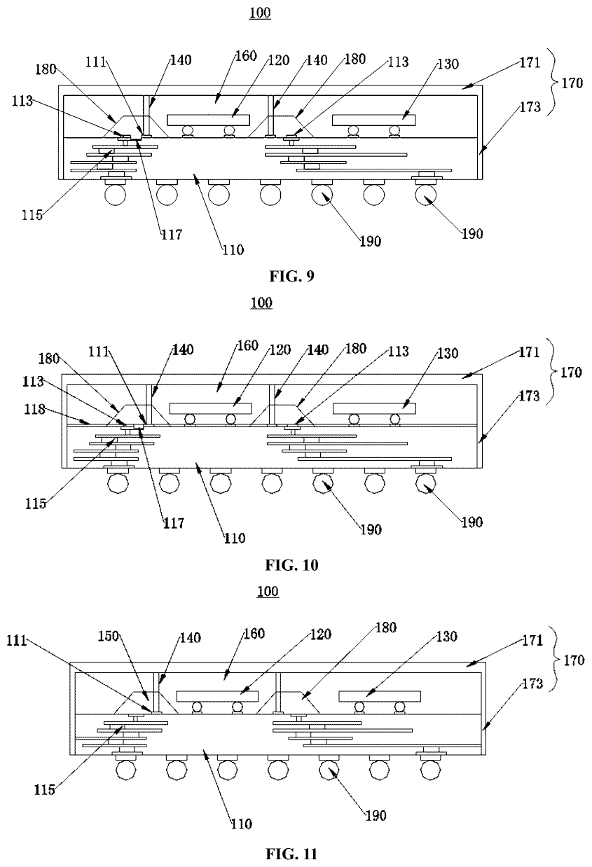

In conjunction with FIG. 9, in one or more embodiments, a groove 117 is arranged on the substrate 110, with partial grounding wiring layer 115 exposed from the groove 117. The groove 117 is arranged therein with an underfill 180, wherein the underfill 180 is a conductive adhesive, and the underfill 180 is configured to connect the wire-bonding pads 111 and the grounding pads 113. This arrangement allows for the electrical connection between the wire-bonding pads 111 and the grounding pads 113, and also enhances the bonding strength of the conductive adhesive and the bonding strength between the substrate 110 and the encapsulating body 160. Since the underfill 180 achieves the electrical connection between the grounding pads 113 and the wire-bonding pads 111, the edge wire 150 can be omitted. In some embodiments, both the edge wire 150 and the groove 117 can be omitted, and the connection between the grounding pads 113 and the wire-bonding pads 111 is solely achieved by the underfill 180, without specific limitations herein. In conjunction with FIG. 10, a solder mask 118 is formed on the substrate 110, with the grounding pads 113 and the wire-bonding pads 111 exposed from the solder mask 118. Optionally, a groove 117 is arranged on the solder mask 118. The groove 117 is arranged therein with the underfill 180, wherein the underfill 180 is a conductive adhesive, and the underfill 180 is configured to connect the wire-bonding pads 111 and the grounding pads 113. Of course, in some embodiments, the solder mask 118 can be omitted. In some embodiments, the solder mask 118 is not provided on the substrate 110, and the grounding pads 113 and the wire-bonding pads 111 are directly arranged on the substrate 110, with multiple wire-bonding pads 111 interconnected together to form a continuous pad (trace). In some other embodiments, the multiple wire-bonding pads 111 are arranged spaced apart to form a cage-like structure or an open structure (e.g., L-shaped, U-shaped, T-shaped) as a whole.

In conjunction with FIG. 11, the substrate 110 is provided therein with a grounding wiring layer 115, wherein the grounding wiring layer 115 extends to the sidewall of the substrate 110 and electrically connects with the shielding metal layer 170. This arrangement can allow for the omission of the grounding pads 113 on the substrate 110, thus enabling a simpler structure and a reduction in the number of the grounding wiring layers 115. It is beneficial to reduce the effects of parasitic currents or parasitic capacitance, thereby enhancing the electromagnetic shielding effectiveness. Optionally, a solder mask 118 is formed on the substrate 110, with the wire-bonding pads 111 exposed from the solder mask 118.

In conjunction with FIG. 12, in the embodiment, the grounding pads 113 can be designed as an equipotential grounding signal layer. This can enable equipotential signal connections across multiple regions to form an equipotential circuit. For example, the substrate 110 can be provided with a first shielding region A and a second shielding region B, where the electromagnetic interference occurs within the circuits of regions A and B. The interference is in the form of, for example, common mode interference or differential mode interference. By designing the shielding wires 140 around the circuit, the interference signals generated within the circuits can be electromagnetically shielded by the shielding wires 140, thereby preventing mutual interference between regions A and B and improving the electromagnetic shielding performance. Additionally, by separately designing the shielding wires 140 in regions A and B to connect with the grounding pads 113 and metal layers, an equipotential signal connection between regions A and B can be achieved, thus forming an equipotential circuit that prevents mutual interference between regions A and B.

Of course, depending on the actual situation, the shielding regions on the substrate 110 are not limited to one or two; there could be three or more. Multiple shielding regions, in a number of three or more, can also be interconnected to form an equipotential circuit to avoid mutual interference between the shielding regions.

The features of the various embodiments described above can be combined in any manner that does not cause conflict, resulting in more possible embodiments, which will not be detailed further herein.

The embodiments of the present disclosure provide an electromagnetic shielding packaging method, including providing a substrate 110, wherein the substrate 110 is provided with a shielding region and a non-shielding region, the substrate 110 is provided with wire-bonding pads 111, the wire-bonding pads 111 enclose to form the shielding region, and a grounding wiring layer 115 extending to the sidewall of the substrate 110 is provided within the substrate 110; mounting a first device 120 in the shielding region; mounting a second device 130 in the non-shielding region; bonding a shielding wire 140 on the wire-bonding pad 111; forming an encapsulation 160 on the substrate 110 that covers the first device 120, the second device 130, and the shielding wire 140, wherein the shielding wire 140 is exposed from the encapsulation 160; and forming a shielding metal layer 170 that is electrically connected to both the shielding wire 140 and the grounding wiring layer 115 on the surface of the encapsulation 160.

The embodiments of the present disclosure provide an electromagnetic shielding packaging method, including providing a substrate 110, wherein the substrate 110 is provided with a shielding region and a non-shielding region, the substrate 110 is provided with wire-bonding pads 111 and the grounding pad 113, the wire-bonding and pads 111 enclose to form the shielding region, and the grounding pad 113 is located farther from the shielding region relative to the wire-bonding pad 111; mounting a first device 120 in the shielding region; mounting a second device 130 in the non-shielding region; bonding a shielding wire 140 on the wire-bonding pad 111; bonding an edge wire 150 on the grounding pad 113; forming an encapsulation 160 on the substrate 110 that covers the first device 120, the second device 130, the shielding wire 140, and the edge wire 150, wherein the shielding wire 140 is exposed from the encapsulation 160; and forming a shielding metal layer 170 that is electrically connected to the shielding wire 140 on the surface of the encapsulation 160.

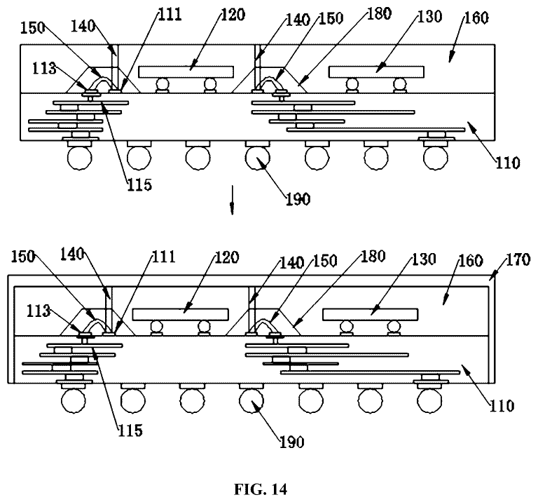

In one or more embodiments, in conjunction with FIGS. 13 and 14, the embodiments of the present disclosure provide an electromagnetic shielding structure 100 that is fabricated as follows.

A substrate 110 including the grounding pads 113 and the wire-bonding pads 111 is provided, wherein the substrate 110 is divided into a shielding region enclosed by the wire-bonding pads 111 and the remaining non-shielding region. The substrate 110 can be a silicon substrate, PCB board, MIS substrate, ceramic substrate, or similar. The grounding pads 113 and the wire-bonding pads 111 are designed separately.

The first device 120 and the second device 130 are mounted on the substrate 110, wherein the first device 120 is located in the shielding region, and the second device 130 is located in the non-shielding region. The first device 120 and the second device 130 can be chips or other components. The types and quantities of the first device 120 and the second device 130 can be flexibly adjusted according to actual needs. For example, the first device 120 can be an RF chip, and the second device 130 can be a power amplifier chip.

Vertical metal wires are bonded to the wire-bonding pads 111 to form the shielding wires 140. The edge wire 150 is bonded between the grounding pads 113, and the edge wire 150 is located on the side of the shielding wire 140 which is farther from the first device 120. It can be understood that the edge wire 150 can be bonded between two grounding pads 113 or between a grounding pad 113 and a wire-bonding pad 111. Preferably, the edge wire 150 is bonded between two grounding pads 113.

The underfill 180 is applied along the shielding wire 140 and the edge wire 150, such that the shielding wire 140 and the edge wire 150 are electrically connected by the underfill 180. Optionally, the underfill 180 covers the edge wire 150. In this embodiment, the height of the edge wire 150 is lower than the height of the shielding wire 140, so the underfill 180 covers part of the height of the shielding wire 140. The underfill 180 facilitates enhancing the strength of the edge wire 150 and the shielding wire 140, thereby improving the electromagnetic shielding effect in the edge region.

Encapsulation is carried out. The first device 120, the second device 130, the shielding wire 140, the edge wire 150, and the underfill 180 on the substrate 110 are encapsulated for protection, so as to form an encapsulation 160. The material of the encapsulation 160 adopts high thermal conductivity encapsulation material, such as an epoxy-based resin or silicone-based resin with added high thermal conductivity materials. The high thermal conductivity materials include, but are not limited to, alumina thermal powder and nano-alumina, to achieve high thermal conductivity and improved heat dissipation performance. It is understood that due to the provision of the edge wire 150, the edge wire 150 can block the encapsulation mold flow, thus reducing the impact of the encapsulation mold flow on the vertical shielding wire 140. This prevents deformation of the vertical shielding wire 140 due to impact by mold flow, which will enlarge the gaps between the shielding wires 140 and allow stray waves to pass through the gaps therein, affecting the electromagnetic shielding effect.

The upper surface of the encapsulation 160 is ground to expose the shielding wire 140.

Solder balls are implanted on the side of the substrate 110 away from the encapsulation 160 to form the solder balls 190. The grounding function is realized by the ground pin substrate corresponding to the solder ball 190.

The encapsulated product is sawed into individual units, which are performed by sputtering to form the shielding metal layer 170 on the upper surface and side surfaces of the encapsulation 160. The shielding metal layer 170 is electrically connected to the exposed shielding wire 140 on the surface of the encapsulation 160, thus completing the fabrication of the electromagnetic shielding structure 100.

In summary, the electromagnetic shielding structure 100 and the packaging method provided by the embodiments of the present disclosure have beneficial effects in several aspects as follows.

The electromagnetic shielding structure 100 and the packaging method are provided in the embodiments of the present disclosure. By separately designing the wire-bonding pad 111 and the grounding pad 113, and designing the grounding pad 113 farther from the shielding region relative to the wire-bonding pad 111, this helps to reduce the number and length of grounding wiring layers 115 in the substrate 110. As a result, parasitic effects and capacitive effects between multiple wiring layers 116 in the substrate 110 are reduced, thereby enhancing the electromagnetic shielding effect. In addition, the embodiment also includes a shielding metal layer 170, with the shielding metal layer 170 and the shielding wire 140 each providing electromagnetic shielding functions, thereby enhancing the electromagnetic shielding effect.

The above is only a preferred embodiment of the present disclosure, which is not intended to limit, and the present disclosure may have various changes and variations for those skilled in the art. Any modification, equivalent substitution, improvement, etc. made within the spirit and principles of the present disclosure shall be included in the scope of protection of the present disclosure.

### INDUSTRIAL PRACTICALITY

The embodiment of the present disclosure provides an electromagnetic shielding structure and a packaging method. By separately designing the wire-bonding pad and the grounding pad, and designing the grounding pad farther from the shielding region relative to the wire-bonding pad, this helps to reduce the number and length of grounding wiring layers in the substrate. As a result, parasitic effects and capacitive effects between multiple wiring layers in the substrate are reduced, thereby enhancing the electromagnetic shielding effect. In addition, the embodiment also includes a shielding metal layer, with the shielding metal layer and the shielding wire each providing electromagnetic shielding functions, thereby enhancing the electromagnetic shielding effect.

Additionally, it is important to note that the electromagnetic shielding structure and packaging method provided in the embodiments of the present disclosure are reproducible and applicable in various industrial applications. For example, the electromagnetic shielding structure and packaging method provided in the embodiments of the present disclosure can be applied in the technology field of semiconductor packaging.

What is claimed is:

1. An electromagnetic shielding structure, comprising:
a substrate, wherein the substrate is provided with a shielding region and a non-shielding region, the substrate is provided with a wire-bonding pad and a grounding pad, and the grounding pad is located farther from the shielding region relative to the wire-bonding pad;
a first device, arranged in the shielding region;
a second device, arranged in the non-shielding region;
a shielding wire, wherein the shielding wire is electrically connected to the wire-bonding pad;
an edge wire, wherein the edge wire is electrically connected to the grounding pad, the edge wire is located on a side of the shielding wire that is farther from the shielding region, and
the grounding pad and the wire-bonding pad are electrically connected;
an encapsulation, wherein the encapsulation encapsulates the first device, the second device, the shielding wire, and the edge wire, and the shielding wire is exposed from the encapsulation; and
a shielding metal layer, wherein the shielding metal layer covers the encapsulation, and the shielding metal layer is electrically connected to the shielding wire.

2. The electromagnetic shielding structure according to claim 1, wherein a grounding wiring layer is provided within the substrate, a projection of the grounding wiring layer on a surface of the substrate is located in the non-shielding region, and the grounding pad is electrically connected to the grounding wiring layer.

3. The electromagnetic shielding structure according to claim 1, wherein the grounding pad and the wire-bonding pad are connected using metal wires and/or conductive adhesive.

4. The electromagnetic shielding structure according to claim 1, wherein the shielding metal layer comprises a top metal layer and a sidewall metal layer that are connected, a shielding barrier is formed around the first device, and the shielding barrier is jointly formed by the sidewall metal layer and multiple shielding wires.

5. The electromagnetic shielding structure according to claim 4, wherein the sidewall metal layer and the multiple shielding wires are located on the same side of the first device, a projection region of the sidewall metal layer on a side surface of the encapsulation and a projection region of the multiple shielding wires on the side surface of the encapsulation overlap at least partially, to make dual-layer shielding.

6. The electromagnetic shielding structure according to claim 4, wherein the sidewall metal layer and the multiple shielding wires are located on different sides of the first device to make single-layer shielding.

7. The electromagnetic shielding structure according to claim 1, wherein the shielding metal layer comprises a top metal layer and a sidewall metal layer that are connected, with at least partial wire-bonding pads exposed from a sidewall of the encapsulation to electrically connect with the sidewall metal layer.

8. The electromagnetic shielding structure according to claim 7, wherein the shielding wires are provided on the at least partial wire-bonding pads that are exposed from the sidewall of the encapsulating body and is electrically connected to the at least partial wire-bonding pads.

9. The electromagnetic shielding structure according to claim 7, wherein the substrate is provided with multiple grounding pads, and the grounding pads are electrically connected to any of the wire-bonding pads.

10. The electromagnetic shielding structure according to claim 1, wherein the wire-bonding pad is arranged in the shielding region, multiple grounding pads are arranged in the non-shielding region, and at least two of the grounding pads are electrically connected by the edge wire, with one of the grounding pads and the wire-bonding pad connected through a wiring layer.

11. The electromagnetic shielding structure according to claim 1, wherein the shielding metal layer covers the encapsulation and a sidewall of the substrate.

12. The electromagnetic shielding structure according to claim 1, wherein a solder mask is provided on the substrate, with the grounding pad and the wire-bonding pad exposed from the solder mask.

13. The electromagnetic shielding structure according to claim 2, wherein a groove is provided on the substrate, with partial grounding wiring layer exposed from the groove; a conductive adhesive is provided within the groove; and the conductive adhesive is configured to connect the wire-bonding pad and the grounding pad.

14. The electromagnetic shielding structure according to claim 13, wherein a solder mask is provided on the substrate, and the groove is provided on the solder mask.

15. The electromagnetic shielding structure according to claim 1, further comprising a underfill, wherein the underfill covers the edge wire and partially covers the shielding wire.

16. The electromagnetic shielding structure according to claim 1, wherein the grounding pad is designed as an equipotential grounding signal layer.

17. An electromagnetic shielding structure, comprising:
a substrate, wherein the substrate is provided with a shielding region and a non-shielding region, the substrate is provided with wire-bonding pads, the wire-bonding pads form the shielding region, and a grounding wiring layer is provided within the substrate;
a first device, arranged in the shielding region;
a second device, arranged in the non-shielding region;
a shielding wire, wherein the shielding wire is electrically connected to the wire-bonding pads;
an encapsulation, wherein the encapsulation encapsulates the first device, the second device, and the shielding wire, and the shielding wire is exposed from the encapsulation; and
a shielding metal layer, wherein the shielding metal layer covers the encapsulation, and the shielding metal layer is electrically connected to the shielding wire; and
the grounding wiring layer extends to a sidewall of the substrate and is electrically connected to the shielding metal layer.

18. The electromagnetic shielding structure according to claim 17, wherein a solder mask is provided on the substrate, with the wire-bonding pads exposed from the solder mask.

19. An electromagnetic shielding packaging method, comprising:
providing a substrate, wherein the substrate is provided with a shielding region and a non-shielding region, the substrate is provided with wire-bonding pads, the wire-bonding pads form the shielding region, and a grounding wiring layer extending to a sidewall of the substrate is provided within the substrate;
mounting a first device in the shielding region;
bonding a shielding wire on the wire-bonding pad;
forming an encapsulation on the substrate that covers the first device and the shielding wire, wherein the shielding wire is exposed from the encapsulation; and
forming a shielding metal layer that is electrically connected to both the shielding wire and the grounding wiring layer on a surface of the encapsulation.

20. An electromagnetic shielding packaging method, comprising:
providing a substrate, wherein the substrate is provided with a shielding region and a non-shielding region, the substrate is provided with wire-bonding pads and grounding pads, the wire-bonding pads form the shielding region, and the grounding pads are located farther from the shielding region relative to the wire-bonding pads;
mounting a first device in the shielding region;
bonding shielding wires on the wire-bonding pads;
bonding edge wires on the grounding pads;
forming an encapsulation on the substrate that covers the first device, the shielding wires, and the edge wires, wherein the shielding wires are exposed from the encapsulation; and
forming a shielding metal layer on a surface of the encapsulation that is electrically connected to the shielding wires, respectively
